(19) United States
(12) Patent Application Publication
(10) Pub. No.: US 2015/0093518 A1
(43) Pub. Date: Apr. 2, 2015

(54) HEAT TREATMENT APPARATUS AND HEAT TREATMENT METHOD

(71) Applicant: TOKYO ELECTRON LIMITED, Tokyo (JP)

(72) Inventors: Tomihiro YONENAGA, Nirasaki City (JP); Cheoljung KIM, Nirasaki City (JP); Yumiko KAWANO, Nirasaki City (JP)

(21) Appl. No.: 14/499,565

(22) Filed: Sep. 29, 2014

(30) Foreign Application Priority Data
Sep. 30, 2013 (JP) 2013-204023

(51) Int. Cl. C23C 14/28; C23C 14/54

(52) U.S. Cl. CPC C23C 14/28; C23C 14/541; C23C 14/542
USPC 427/591; 118/724

(57) ABSTRACT

The present disclosure provides an apparatus of performing a heat treatment with respect to a substrate mounted within a processing vessel, including: a substrate mounting stand including an inner portion configured to transfer heat to a central portion of the substrate and a heat generation regulating portion configured to generate heat through an induction heating; a magnetic field forming mechanism configured to form magnetic fields with alternating current power and to inductively heat the heat generation regulating portion; a power supply unit configured to supply the alternating current power to the magnetic field forming mechanism; a temperature measuring unit configured to measure a temperature of the heat generation regulating portion; a control unit configured to control the alternating current power; and a gas supply unit configured to supply a treatment gas to the substrate mounted on the mounting stand.

### CROSS-REFERENCE TO RELATED APPLICATION

This application claims the benefit of Japanese Patent Application No. 2013-204023, filed on Sep. 30, 2013, in the Japan Patent Office, the disclosure of which is incorporated herein in its entirety by reference.

### TECHNICAL FIELD

The present disclosure relates to a heat treatment apparatus and a heat treatment method for heating a substrate through an induction heating of a mounting stand on which the substrate is mounted and for performing heat treatment by supplying treatment gas to the substrate.

### BACKGROUND

For a batch type apparatus for performing a process of forming thin films with respect to a plurality of semiconductor wafers (hereinafter referred to as “wafers”) as substrates simultaneously, there is known a vertical heat treatment apparatus that includes a wafer boat, which holds the wafers, such as a shelf and a processing vessel (reaction tube) for air-tightly accommodating the wafer boat inside the processing vessel. A gas injector extending in an up-down direction so as to discharge a film-forming gas toward the respective wafers is installed between an inner wall surface of the processing vessel and the wafer boat.

This heat treatment apparatus employs so-called a hot wall method in which the respective wafers are heated by a heater installed outside the processing vessel. Therefore, the outer periphery region of a wafer located at an arbitrary position is positioned closer to the heater than the central region of the wafer. For that reason, the temperature of the central region is lower than the temperature of the outer periphery region. Thus, the temperature distribution of the wafer is so-called valley-shaped.

In the hot wall type film-forming apparatus, the processing vessel is heated as a whole. Thus, as the diameter of the wafer becomes greater, the processing vessel grows larger in size and the heat capacity increases. This leads to an increase in the time and energy consumption required for heating the respective wafers. Under the circumstances, a cold wall type apparatus has been studied as an alternative for the hot wall type apparatus.

That is to say, the cold wall type apparatus has a configuration in which an electromagnet is installed outside the processing vessel and high-frequency power is supplied to the electromagnet (electromagnetic induction coil). By switching the direction of magnetic fields at a high speed, a wafer mounting stand is heated by induced current. Then, the respective wafers are heated through the mounting stand. This eliminates the need to heat the processing vessel. Therefore, as compared to the hot wall type apparatus, it is possible to shorten the heating time and to save the energy.

There is also disclosed a method in which, in a cold wall type apparatus, a susceptor for holding a wafer is divided into an inner periphery portion and an outer periphery portion to control the heat generation distribution at the susceptor. In addition, there is known a cold wall type apparatus in which a ring-shaped notch is formed along a circumferential direction of an outer periphery portion of a susceptor. However, in the aforementioned technology, when forming a thin film on the surface of the wafer, no consideration is given to the uniformity of a film thickness of a thin film at the plane of the wafer.

### SUMMARY

Some embodiments of the present disclosure provide a technique that, when heating a substrate mounted on a mounting stand through an induction heating of the mounting stand and when performing a heat treatment by supplying a treatment gas to the substrate, can perform the heat treatment with good uniformity at the plane of the substrate.

According to one embodiment of the present disclosure, there is provided an apparatus of performing a heat treatment with respect to a substrate mounted within a processing vessel, including: a mounting stand on which the substrate is mounted, the mounting stand including an inner portion configured to transfer heat from an outer periphery portion of the substrate to a central portion thereof and a heat generation regulating portion annularly installed at the outer periphery portion of the inner portion so as to extend along a circumferential direction and configured to generate heat through an induction heating; a magnetic field forming mechanism designed to form magnetic fields with alternating current power supplied thereto and configured to inductively heat the heat generation regulating portion by allowing magnetic fluxes parallel to a mounting surface of the inner portion to pass through the heat generation regulating portion; a power supply unit configured to supply the alternating current power to the magnetic field forming mechanism; a temperature measuring unit configured to measure a temperature of the heat generation regulating portion; a control unit configured to control the alternating current power supplied to the magnetic field forming mechanism, based on a temperature value measured by the temperature measuring unit and a target temperature; and a gas supply unit configured to supply a treatment gas to the substrate mounted on the mounting stand from a peripheral edge of the mounting stand, the heat generation regulating portion having a thickness dimension set equal to or smaller than two times of a skin depth which is decided based on a magnetic permeability and resistivity of the heat generation regulating portion and a frequency of the alternating current power.

According to another embodiment of the present disclosure, there is provided an apparatus of performing a heat treatment with respect to a substrate mounted within a processing vessel, including: a mounting stand including an inner portion on which the substrate is mounted and a heat generation regulating portion installed at a peripheral edge portion of the inner portion and configured to generate heat through an induction heating, the heat generation regulating portion including an outer end surface and a notch cut on the outer end surface to annularly extend along a circumferential direction such that a temperature of a central portion of the inner portion becomes higher than a temperature of the heat generation regulating portion; a magnetic field forming mechanism designed to form magnetic fields with alternating current power supplied thereto and configured to inductively heat the heat generation regulating portion by allowing magnetic fluxes parallel to a mounting surface of the inner portion to pass through the heat generation regulating portion; a power supply unit configured to supply the alternating current power to the magnetic field forming mechanism; a temperature measuring unit configured to measure the temperature of the heat generation regulating portion; a control unit configured to control the alternating current power supplied to the magnetic field forming mechanism, based on a temperature value measured by the temperature measuring unit and a target temperature; and a gas supply unit configured to supply a treatment gas to the substrate mounted on the mounting stand from a peripheral edge of the mounting stand.

According to another embodiment of the present disclosure, there is provided a method of performing a heat treatment with respect to a substrate mounted within a processing vessel, including: mounting the substrate on an inner portion; inductively heating a heat generation regulating portion annularly installed in an outer periphery portion of the inner portion to extend along a circumferential direction, by supplying alternating current power to a magnetic field forming mechanism and by allowing magnetic fluxes parallel to a mounting surface of the inner portion to pass through the heat generation regulating portion, and transferring heat from the heat generation regulating portion to a central portion of the inner portion through the inner portion; measuring a temperature of the heat generation regulating portion; controlling the alternating current power supplied to the magnetic field forming mechanism, based on a measured temperature value of the heat generation regulating portion and a target temperature; and supplying a treatment gas to the substrate mounted on the inner portion from a peripheral edge of the inner portion, the heat generation regulating portion having a thickness dimension set equal to or smaller than two times of a skin depth which is decided based on a magnetic permeability and resistivity of the heat generation regulating portion and a frequency of the alternating current power, whereby the heat treatment is performed in such a state that a temperature of a central portion of the substrate is higher than a temperature of a peripheral edge portion of the substrate.

According to another embodiment of the present disclosure, there is provided a method of performing a heat treatment with respect to a substrate mounted within a processing vessel, including: mounting the substrate on an inner portion; inductively heating a heat generation regulating portion annularly installed in an outer periphery portion of the inner portion and provided with an outer end surface and a notch cut on the outer end surface to annularly extend along a circumferential direction, by supplying alternating current power to a magnetic field forming mechanism and by allowing magnetic fluxes parallel to a mounting surface of the inner portion to pass through the heat generation regulating portion, and transferring heat from the heat generation regulating portion to a central portion of the inner portion through the inner portion such that a temperature of a central portion of the substrate becomes higher than a temperature of a peripheral edge portion of the substrate; measuring a temperature of the heat generation regulating portion; controlling the alternating current power supplied to the magnetic field forming mechanism, based on a measured temperature value of the heat generation regulating portion and a target temperature; and supplying a treatment gas to the substrate mounted on the inner portion from a peripheral edge of the inner portion.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical sectional view showing one embodiment of a film-forming apparatus according to the present disclosure.

FIG. 2 is a horizontal sectional view of the film-forming apparatus.

FIG. 3 is a vertical sectional view showing one embodiment of a susceptor installed in the film-forming apparatus.

FIG. 4 is a partially cutaway perspective view of the susceptor.

FIG. 5 is a plan view schematically showing the state of magnetic fields formed by a coil unit for generating an induced current in the susceptor.

FIGS. 6 and 7 are plan views schematically showing the state of the induced current generated in the susceptor.

FIG. 8 is a schematic diagram showing an induced current generated in a conventional susceptor, a temperature distribution of the wafer and a thin film thickness distribution.

FIG. 9 is a schematic diagram showing an induced current generated in the susceptor according to the present disclosure, a temperature distribution of the wafer and a thin film thickness distribution.

FIG. 10 is a perspective view showing one embodiment of a transfer mechanism for performing delivery of a wafer to the susceptor.

FIG. 11 is a side view showing an operation in which the wafer is delivered to the susceptor by the transfer mechanism.

FIG. 12 is a side view showing an operation in which the wafer is delivered to the susceptor by the transfer mechanism.

FIG. 13 is a vertical sectional view showing another embodiment of the susceptor.

FIG. 14 is a schematic diagram showing the susceptor according to another embodiment.

FIG. 15 is a vertical sectional view showing a further another embodiment of the susceptor.

FIG. 16 is a schematic diagram showing the susceptor according to the further another embodiment.

FIG. 17 is a vertical sectional view showing another embodiment of the transfer mechanism.

FIG. 18 is a plan view showing a susceptor to which the transfer mechanism according to another embodiment is applied.

FIG. 19 is a characteristic diagram showing a heat generation quantity obtained in an embodiment of the present disclosure.

FIG. 20 is a characteristic diagram showing a temperature distribution obtained in an embodiment of the present disclosure.

FIG. 21 is a characteristic diagram showing a temperature distribution obtained in an embodiment of the present disclosure.

FIGS. 22 and 23 are vertical sectional views showing a conventional susceptor.

FIGS. 24 and 25 are characteristic diagrams showing a temperature distribution obtained in the conventional susceptor.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

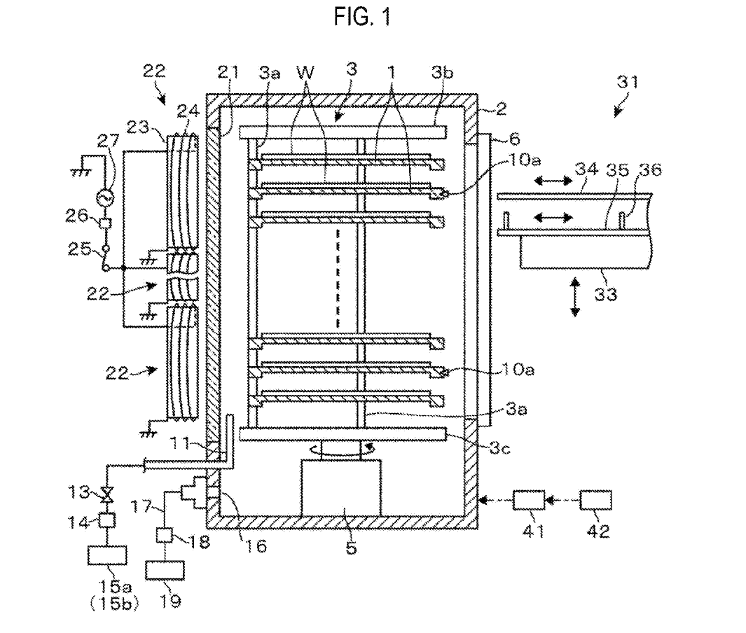

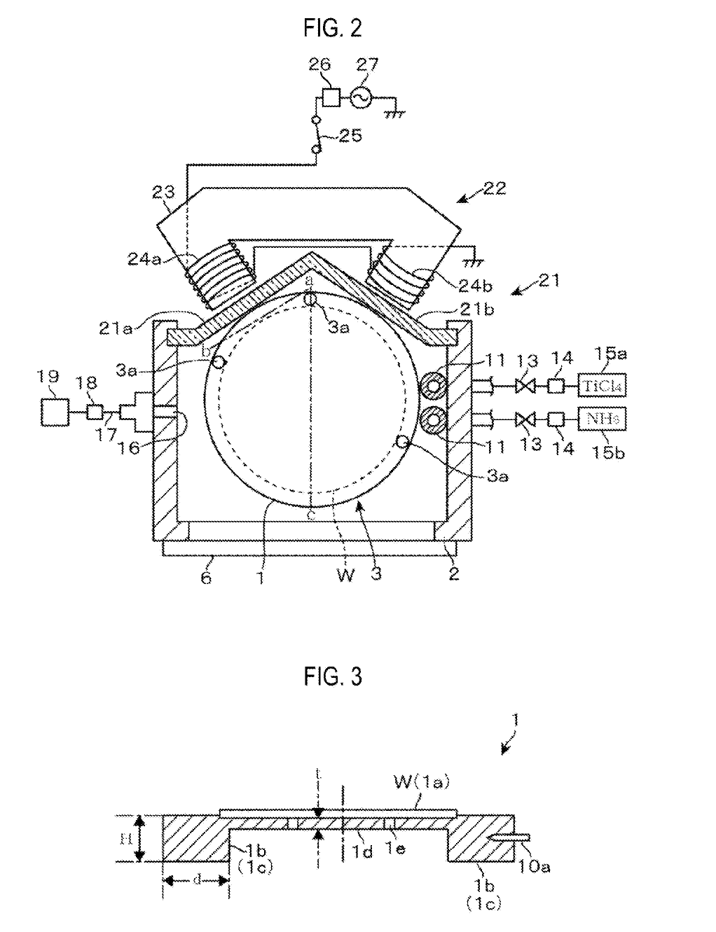

One example of an embodiment in which a heat treatment apparatus according to the present disclosure is applied to a film-forming apparatus will be described with reference to FIGS. 1 and 2. The film-forming apparatus is configured by so-called a cold wall type apparatus in which susceptors 1, as mounting stands for holding wafers W, are heated by an induction heating from the outside of a processing vessel 2 and then the wafers W are heated through the susceptors 1. The susceptors 1 are made of a carbon-based material, e.g., graphite. The processing vessel 2 is formed into a substantially box-like shape. A window 21 is air-tightly installed at one of side surface portions, e.g., a left side surface portion in FIG. 1. An opening that can be opened and closed by a gate valve 6 is formed at the other of the side surface portions, e.g., a right side surface portion in FIG. 1. The susceptors 1 are schematically depicted in FIG. 1.

The aforementioned susceptors 1 for holding the wafers W having a circular shape when seen in a plan view are accommodated within the processing vessel 2 at a plurality of stages (twelve stages in this embodiment) in an up-down direction. The outer periphery portion of each of the susceptors 1 is supported by support posts 3a, which are vertically extended, at a plurality of points (three points in this embodiment) such that a gap region is formed between the neighboring susceptors 1. That is to say, the susceptors 1 are held by the support posts 3a. The susceptors 1 and the support posts 3a constitute a wafer holder 3.

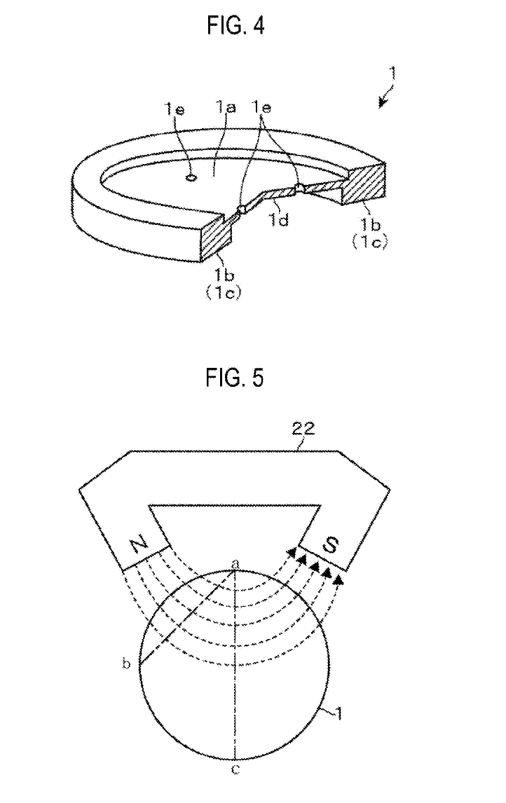

As shown in FIGS. 3 and 4, each of the susceptors 1 is formed into a substantially disc-like shape (plate-like shape). A mounting region 1a on which the wafer W is dropped and mounted is formed on an upper surface of each of the susceptors 1. A peripheral edge portion of a lower surface of each of the susceptors 1 protrudes annularly (in a ring shape) downward along a circumferential direction so as to include a region that adjoins an outer edge of the wafer W mounted on each of the susceptors 1 when seen in a plan view, thereby forming a protrusion portion 1b. Then, magnetic lines (magnetic flux) formed by a coil unit 22 to be described later pass through the protrusion portion 1b, whereby an induced current flows at the protrusion portion 1b. Thus, the protrusion portion 1b constitutes a heat generation regulating portion 1c for regulating heat generation by the induced current.

The width dimension d of the protrusion portion 1b is set to be equal to, e.g., 20 mm. The thickness dimension H of the heat generation regulating portion 1c is set to be equal to, e.g., 15 mm or less. A region that exists at the inner side of the heat generation regulating portion 1c and supports the inner portion of the wafer W is referred to as an “inner portion 1d”. The thickness dimension t of the inner portion 1d is set to be smaller than the thickness dimension H (equal to 5 mm in this embodiment). The reason for setting the dimensions d, H and t in this way will be described later in detail. In FIG. 3, reference symbol 1e designates through-holes through which the below-described lifter pins 36 for performing delivery of the wafer w to each of the susceptors 1 are elevated and lowered. In FIG. 3, reference symbol 10a designates a thermocouple for measuring the temperature of the heat generation regulating portion 1c of each of the susceptors 1. The thermocouple 10a is inserted into the side surface of the protrusion portion 1b of each of the susceptors 1. In FIG. 4, the susceptor 1 is depicted in a partially cutaway condition.

An opening that can be air-tightly opened and closed by a gate valve 6 is formed at the side surface portion of the processing vessel 2 at the lateral side of the wafer holder 3, so that the wafer W can be delivered to each of the susceptors 1 through the opening. A configuration (transfer mechanism 31) for delivering the wafer W to each of the susceptors 1 will be described later. In FIG. 1, reference symbol 5 designates a rotating mechanism, such as a motor or the like, for rotating the wafer holder 3 about a vertical axis. In FIG. 1, reference symbols 3b and 3c designate a top plate and a bottom plate, respectively installed above and below a stacking region of the susceptors 1.

Gas injectors 11 that constitute a gas supply unit for supplying a film-forming gas into the processing vessel 2 are air-tightly inserted through the side wall of the processing vessel 2 in the vicinity of the lower end of the processing vessel 2. A tip portion (upper end portion) of each of the gas injectors 11 is opened between the bottom plate 3c of the wafer holder 3 and the susceptor 1 adjoining the bottom plate 3c at the upper side thereof. As shown in FIG. 2, two gas injectors 11 are installed in this embodiment. The base end portions (upstream end portions) of the gas injectors 11 are respectively connected through valves 13 and flow rate control units 14 to a reservoir 15a for retaining a source gas, e.g., a titanium tetrachloride (TiCl₄) gas and a reservoir 15b for retaining a reaction gas, e.g., an ammonia (NH₃) gas. A titanium nitride (TiN) film is formed on the wafer W by, e.g., an ALD (Atomic Layer Deposition) method in which the source gas and the reaction gas as treatment gases are alternately supplied into the processing vessel 2 or a CVD (Chemical Vapor Deposition) method in which the source gas and the reaction gas are supplied at the same time.

An exhaust port 16 is formed at the lower end sidewall of the processing vessel 2 at a position opposite to the gas injectors 11. An exhaust path 17, which extends from the exhaust port 16, is connected to a vacuum exhaust mechanism 19 such as a vacuum pump or the like, through a pressure regulating unit 18 such as a butterfly valve or the like. In FIG. 1, as explained above, the gas injectors 11 and the exhaust port 16 are combined and depicted with one spot.

One sidewall (e.g., the left sidewall in FIG. 1) of the processing vessel 2 is opened with a substantially rectangle-like shape, so as to cover the arrangement region of the respective susceptors 1 of the aforementioned wafer holder 3. The opening is air-tightly closed by a magnetic-line-transmitting window 21 made of, e.g., quartz or the like. As shown in FIG. 2, the window 21 is bent such that the central portion thereof protrudes outward from the processing vessel 2 when seen in a plan view. Left and right wall surface portions 21a and 21b of the bent region are arranged so as to adjoin the wafer holder 3, respectively. In this way, the processing vessel 2 is formed into a substantially pentagon-like shape when seen in a plan view.

As shown in FIGS. 1 and 2, a coil unit 22 having a magnetic core is installed, as a magnetic field forming mechanism, at the opposite side of the wafer holder 3 through the window 21. That is to say, the coil unit 22 includes a magnetic core 23 arranged outside the processing vessel 2 to extend horizontally and formed of a substantially prism-like magnetic body (e.g., a ferrite body or the like), and coils 24a and 24b formed by winding a copper wire or a copper tube around the outer circumferential surface of the magnetic core 23 from one longitudinal side of the magnetic core 23 toward the other longitudinal side of the magnetic core 23. The surface of the copper wire or the copper tube is coated with an insulating material such as, e.g., a resin or the like.

One longitudinal end portion and the other longitudinal end portion of the magnetic core 23 are horizontally bent toward the wafer holder 3 such that the end portions face the left and right wall surface portions 21a and 21b of the aforementioned window 21. The aforementioned coils 24a and 24b are wound around one end portion and the other end portion of the magnetic core 23. The coils 24a and 24b are serially connected to each other. The coils 24a and 24b are connected to a high-frequency power supply 27 having an output frequency of, e.g., 50 kHz, through a switch 25 and a matcher 26. In this embodiment, the winding direction of the coils 24a and 24b and the wiring of the coils 24a and 24b connected to the high-frequency power supply 27 in the coil unit 22 are set, such that two magnetic pole surfaces having opposite polarities can constitute a U-shaped electromagnet that faces toward the window 21.

As mentioned above, two coils 24a and 24b are serially connected to each other. A terminal of one coil 24a is connected to the high-frequency power supply 27. A terminal of the other coil 24b is grounded. At a certain moment during the supply of high-frequency power to the coils 24a and 24b, if one end portion (magnetic pole face) of the magnetic core 23 wound with one coil 24a becomes the N pole, the other end portion of the magnetic core 23 wound with the other coil 24b becomes the S pole. Therefore, as shown in FIG. 5, one end portion of the magnetic core 23 becomes the N pole and the other end portion of the magnetic core 23 becomes the S pole. Thus, magnetic lines flowing from the N pole toward the S pole and reaching the central portions of the susceptors 1 are formed between one end portion and the other end portion of the magnetic core 23. At another moment during the supply of high-frequency power to the coils 24a and 24b, one end portion of the magnetic core 23 becomes the S pole and the other end portion of the magnetic core 23 becomes the N pole. Thus, in a similar manner, magnetic lines flowing in the direction opposite to the aforementioned direction are formed between one end portion and the other end portion of the magnetic core 23. If the high-frequency power is continuously supplied to the coils 24a and 24b in this manner, the magnetic poles of the opposite end portions of the magnetic core 23 are switched at a high speed. Similarly, the directions of the magnetic lines formed between the opposite end portions are inverted at a high speed.

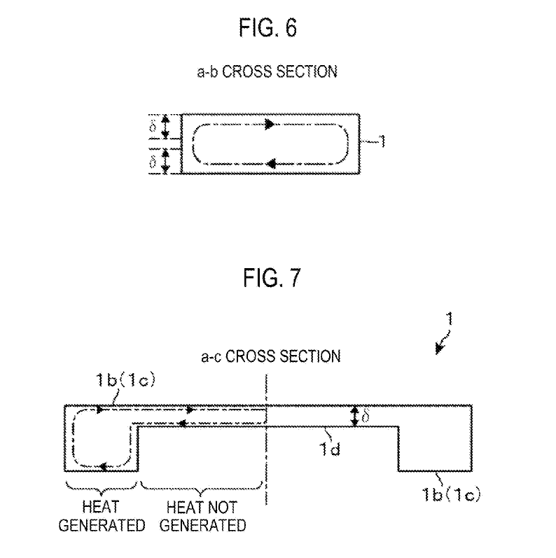

As described above, the opposite end portions of the magnetic core 23 are arranged to adjoin the wafer holder 3 through the window 21. The magnetic pole faces of the opposite end portions of the magnetic core 23 are configured to face the side surfaces of the susceptors 1. For that reason, horizontal magnetic lines (magnetic flux) are formed between the opposite end portions of the magnetic core 23. An induced current is generated in a region where the magnetic lines penetrate the vertical cross sections of the susceptors 1. For example, an a-b cross section of FIG. 5 (a vertical cross section of the susceptor 1 taken at the end position thereof) and an a-c cross section of FIG. 5 (a vertical cross section of the susceptor 1 taken along a substantially radial direction) are shown in FIGS. 6 and 7. As can be noted in FIGS. 6 and 7, there are formed magnetic lines that penetrate the aforementioned cross sections. As set forth above, the directions of the magnetic lines are switched at a high speed. Depending on the switching frequency, an induced current is generated on each of the cross sections as shown in, e.g., FIGS. 6 and 7.

The induced current has a tendency (skin effect) to be pushed toward the outside of the region penetrated by the magnetic lines. The induced current becomes a loop-shaped current that flows over a range of the frequency-dependent depth δ (skin depth) from the surface of the susceptor 1. Thus, the flow path of the induced current is largely affected by the shape of the vertical cross section of the susceptor 1. As shown in FIG. 6, in case of the cross section taken across only the protrusion portion 1b, the thickness dimension H of the protrusion portion 1b is sufficiently greater than the depth δ. For that reason, when the induced current flows in a loop shape, the currents flowing in the opposite directions through the upper and lower flow paths (the flow path passing through a portion near the upper surface of the susceptor 1 and the flow path passing through a portion near the lower surface of the susceptor 1) do not interfere with each other.

As shown in FIG. 7, in case of the cross section including the central portion of the susceptor 1, the flow of the induced current becomes quite different in the protrusion portion 1b and the inner portion 1d, because the thickness dimensions H and t of the protrusion portion 1b and the inner portion 1d largely differ from each other as shown in FIG. 3. The thickness dimension H and the width dimension d of the protrusion portion 1b are sufficiently larger than the depth δ. Therefore, when the induced current flows on the cross section of the protrusion portion 1b in a loop shape, the currents flowing in the opposite directions through the upper, lower, left and right flow paths do not interfere with each other. In contrast, the thickness dimension t of the inner portion 1d is smaller than the depth δ. For that reason, the currents flowing in the opposite directions through the upper and lower flow paths are cancelled each other. Thus, the induced current is substantially reduced. In the susceptor 1, heat is generated by the induced current. Therefore, the amount of heat generated at the protrusion portion 1b where the induced current is not limited governs the heating of the susceptor 1. If the wafer holder 3 is rotated about a vertical axis, the heat generation regulating portion 1c circumferentially passes through the region where the magnetic lines are formed. Thus, the heat generation regulating portion 1c is annularly heated. The inner portion 1d of the susceptor 1 is also heated by the heat transferred from the heat generation regulating portion 1c.

Now, the reason for setting the respective dimensions d, H and t of the susceptor 1 as mentioned above will be described in detail. First, description will be made on the width dimension d of the protrusion portion 1b formed in the peripheral edge portion of the lower surface of the susceptor 1. As mentioned above, the induced current flowing on the cross section of the protrusion portion 1b is affected by the width dimension d of the protrusion portion 1b as well as the thickness dimension H thereof. In order to assure that heat is effectively generated by the induced current, the width dimension d needs to be made sufficiently larger than the depth δ.

If the width dimension d is too large, the heat capacity of the susceptor 1 is increased. Therefore, when heating the susceptor 1, the high-frequency power needs to be made larger. Or, the time required for the temperature of the susceptor 1 to reach a target temperature is prolonged. When the susceptor 1 is cooled after finishing a film-forming process for the wafer W, the susceptor 1 is hard to discharge the heat. As a result, the time required in cooling the susceptor 1 is prolonged. Thus, in the present disclosure, the width dimension d of the protrusion portion 1b is set sufficiently larger than the depth δ as well as not to significantly increase the heat capacity. A specific numerical value range of the width dimension d is from 15 mm to 22.5 mm, which is twice or about three times the depth δ. The thickness dimension t of the inner portion 1d is set so as to minimize the heat capacity while maintaining the strength and machining accuracy of the susceptor 1. In the present embodiment, the susceptor 1 is made of graphite. Therefore, when defined based on the diameter dimension (300 mm) of the wafer W, the thickness dimension t of the inner portion 1d becomes equal to 5 mm.

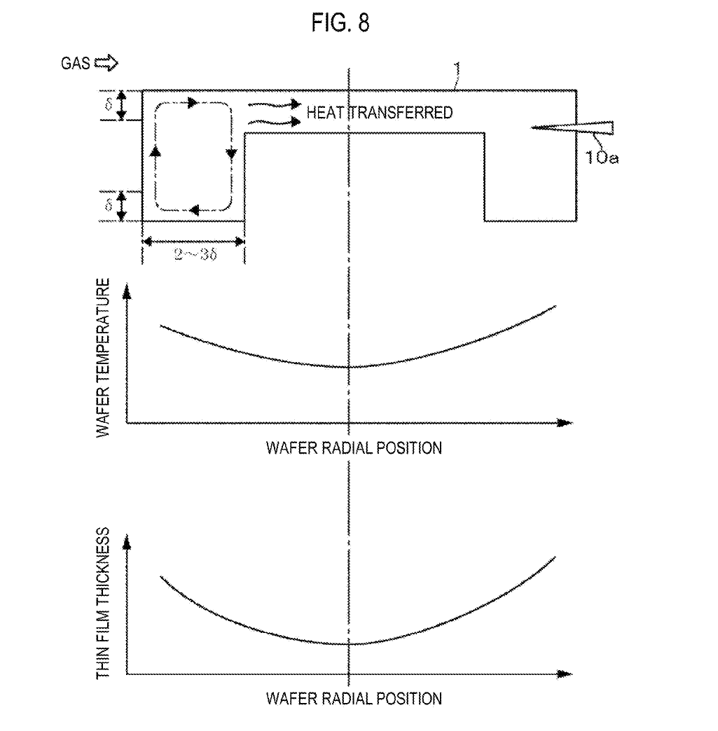

Subsequently, prior to describing the thickness dimension H of the heat generation regulating portion 1c in detail, a conventional configuration and its related problems will be first described. That is to say, the configuration of a conventional susceptor 1 is shown at the upper end in FIG. 8. In the related art, the shape of the susceptor 1 is defined such that a larger amount of heat generation can be obtained by the magnetic lines formed by the coil unit 22. The amount of heat discharge is large in the outer edge portion of the susceptor 1. In order to suppress the temperature fluctuation caused by the heat discharge, it is necessary to increase the heat capacity of the outer edge portion of the susceptor 1. For that reason, the outer edge portion of the susceptor 1 is made thick. Since the magnetic lines formed by the coil unit 22 are oriented in a horizontal direction, the magnetic lines penetrating the outer edge portion of the susceptor 1 are larger in amount than the magnetic lines penetrating the central portion of the susceptor 1. For that reason, as shown at the middle position in FIG. 8, the temperature distribution of the susceptor 1 becomes so-called valley shaped.

When a film-forming process is performed with respect to the wafers W mounted on the susceptors 1, the susceptors 1 are stacked at multiple stages in an up-down direction as mentioned above. In this case, a mechanism for supplying a film-forming gas to the wafers W must have a configuration in which a film-forming gas is supplied to the lateral side of the wafers W. In other words, if the susceptors 1 are stacked one above another, individual gas supply mechanisms need to be installed at the respective susceptors 1 by a method in which a film-forming gas is supplied to the wafers W from above just like a shower. As a result, the height dimension of the apparatus is increased. This makes it difficult to employ the method.

The film-forming gas injected at the lower side within the processing vessel 2 is moved upward within the processing vessel 2 and is supplied to the lateral side of the wafers W. More specifically, the film-forming gas flows from the outer peripheral edges of the wafers W toward the central portions thereof. Thereafter, the film-forming gas is discharged from the central portions toward the outer peripheral edges of the wafers W that differ from the outer peripheral edges at which the film-forming gas is supplied. If the film-forming gas flowing in this way makes contact with the wafers W, the film-forming gas is thermally decomposed. Thus, a decomposed product is deposited. As a result, the amount of the film-forming gas decreases as the film-forming gas flows from the upstream side toward the downstream side in the flow direction of the film-forming gas. Moreover, the film-forming gas is thermally decomposed with ease as the temperature of the wafers W becomes higher.

Accordingly, in the outer periphery portions of the wafers W having a higher temperature and a higher film-forming gas concentration than the central portions of the wafers W, the thermal decomposition of the film-forming gas actively occurs. On the other hand, the central portions of the wafers W are lower in temperature than the outer periphery portions of the wafers W. The film-forming gas is mostly or partially absorbed by thermal decomposition at the outer periphery portions. Consequently, the film-forming gas concentration is lower at the central portions than at the outer periphery portions. For that reason, as shown at the lower end in FIG. 8, the film thickness of the thin films formed on the wafers W is larger at the outer periphery portions than at the central portions. This means that the film thickness becomes so-called valley shaped. That is to say, in the related art configuration, the film thickness of the thin films formed on the wafers W is hard to be uniform in the plane of the wafer W.

In contrast, according to the present disclosure, the thickness dimension H of the heat generation regulating portion 1c is set such that the film thickness of the thin films becomes uniform in the plane of the wafer W. Specifically, the thickness dimension H is set as indicted by the following equation (1):

H≦2×δ (1)

In the equation (1), the δ is represented by the following equation (2):

$$δ = 5.03 \times \sqrt{\frac{ρ}{μ \times f}} \qquad ( 2 )$$

In the equation (2), the δ is a skin depth (cm), the ρ is a specific resistance (μΩ·cm) of a susceptor material, the f is a frequency (Hz) of high-frequency power, and the μ is a magnetic permeability (−) of a susceptor material. In this embodiment, the specific resistance ρ, the frequency f and the magnetic permeability μ are set equal to 1100, 50000 and 1, respectively. The skin depth δ is set equal to 0.74607 cm. Accordingly, the thickness dimension H becomes 15 mm or less.

That is to say, if the high-frequency power is supplied to the coil unit 22 as mentioned above, an induced current flows on the cross section of the protrusion portion 1b of the susceptor 1 due to the horizontal magnetic lines formed by the high-frequency power. The induced current is a loop-shaped current flowing over a range of the depth δ from the surface of the protrusion portion 1b. For that reason, the flow path of the induced current is largely affected by the cross-sectional shape of the protrusion portion 1b. More specifically, if the thickness dimension H of the protrusion portion 1b is sufficiently larger than the skin depth, when the induced current flows in a loop shape, the currents flowing in the opposite directions through the upper and lower flow paths do not interfere with each other. Thus, in this case the currents do not cancel each other out.

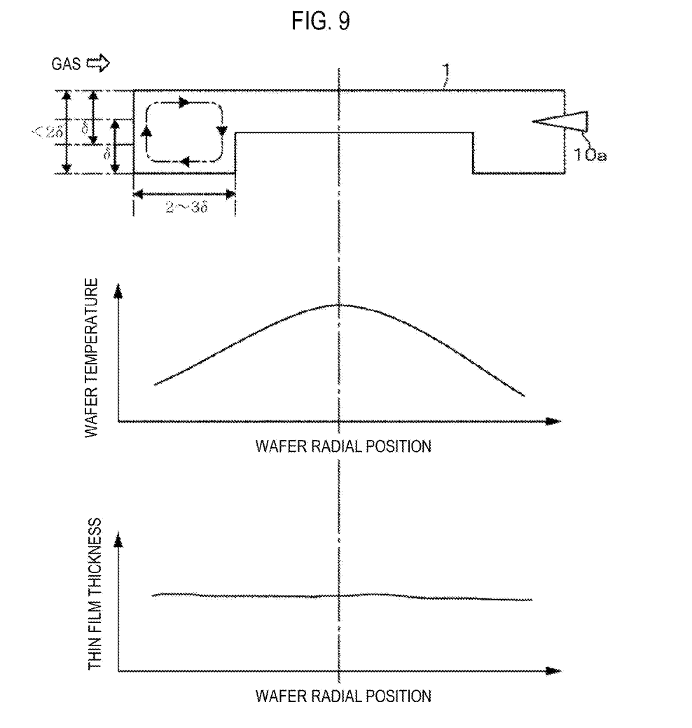

On the other hand, if the thickness dimension H of the protrusion portion 1b is set as indicated by the aforementioned equation (1), when the induced current flows in a loop shape on the cross section of the protrusion portion 1b as shown at the upper end in FIG. 9, the currents flowing in the opposite directions through the upper and lower flow paths interfere with each other. Thus, the currents cancel each other out and the induced current is substantially reduced. As a result, the heat generated at the protrusion portion 1b by the induced current is reduced. Therefore, as compared to the related art configuration described above, the heating efficiency is reduced. Accordingly, when the protrusion portion 1b is heated to an arbitrary target temperature, the present disclosure provides larger electric power supplied to the coil unit 22 than that of the related art configuration.

The temperature of the heat generation regulating portion 1c of the susceptor 1 is measured by the thermocouple 10a inserted into the side surface of the protrusion portion 1b. Therefore, during the time at which the temperature of the heat generation regulating portion 1c reaches a target temperature, it is possible to secure sufficient time and heat amount required in transferring the energy, which is supplied to the heat generation regulating portion 1c, to the central portion of the susceptor 1 as heat. For that reason, as can be noted from the below-described embodiment, the temperature of the central portion of the wafer W becomes higher than the temperature of the peripheral edge portion. As shown at the middle position in FIG. 9, the temperature distribution of the wafer W has a so-called ridge shape. Thus, if a film-forming gas is supplied to the lateral side of the wafer W, it is more difficult for the film-forming gas to be absorbed at the peripheral edge portion having a low temperature than at the central portion. Consequently, the film thickness distribution of the thin film formed on the wafer W becomes substantially flat as shown at the lower end in FIG. 9. That is to say, even in the present disclosure, the concentration of the film-forming gas shows such a distribution that the concentration becomes gradually lowered from the supply side of the film-forming gas toward the discharge side of the film-forming gas. The temperature gradient of the wafer W is adjusted so as to offset the effect of such a distribution of the film-forming gas. Accordingly, the film thickness distribution of the thin film becomes uniform.

Referring back to the description on the configuration of the apparatus, as shown in FIG. 1, the aforementioned coil unit 22 is formed so as to cover (face) a plurality of (six, in this embodiment) susceptors 1 of the wafer holder 3. In this embodiment, three coil units 22 are stacked one above another in order to generate an induced current at the susceptors 1 arranged from the upper end position of the wafer holder 3 to the lower end position thereof. The switch 25, the matcher 26 and the high-frequency power supply 27 are commonly used in these coil units 22. The thermocouple 10a is installed at the susceptor 1 representatively indicating the susceptor temperature among six susceptors 1 governed by each of the coil units 22. The output power of the high-frequency power supply 27 is controlled based on the temperature measured by the thermocouple 10a.

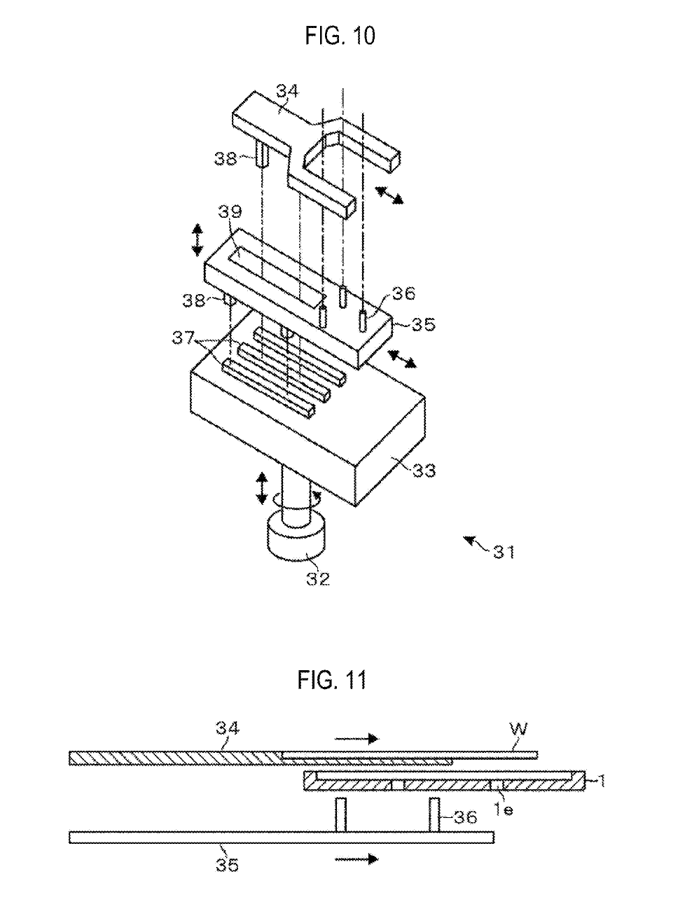

As shown in FIG. 1, a transfer mechanism 31 for performing delivery of the wafer W to the wafer holder 3 is installed at the lateral side of the gate valve 6. Referring to FIG. 10, the transfer mechanism 31 is configured such that it can be rotated about a vertical axis and can be moved up and down by a drive unit 32. A substantially plate-like transfer base 33 is installed on the drive unit 32. Two plate-like arm units 34 and 35 are arranged in stacks on the surface of the transfer base 33 such that the arm units 34 and 35 can move forward and backward along the extended direction of the transfer base 33. The upper arm unit 34 of the arm units 34 and 35 is designed to support the central portion of the lower surface of the wafer W. As shown in FIG. 10, the tip portion of the upper arm unit 34 is bifurcated in a tuning fork shape with the central portion opened. In FIG. 1, some disclosures about the transfer mechanism 31 are partially omitted.

On the other hand, the lower arm unit 35 is designed to perform the up/down movement of the wafer W supported on the upper arm unit 34. Lifter pins 36 installed to penetrate the through-holes 1e of the susceptor 1 are arranged at, e.g., three points, on the upper surface of the tip portion of the lower arm unit 35. The lifter pins 36 and the wafer holding portion of the upper arm unit 34 are disposed so as not to interfere with each other (not to make contact with each other).

The lower arm unit 35 is spaced apart from the upper arm unit 34 by a dimension slightly larger than the sum of the thickness dimension of the susceptor 1 and the length dimension of the lifter pins 36. The lower arm unit 35 is configured such that it can be moved up and down with respect to the upper arm unit 34 by an elevator mechanism which is not shown. In FIG. 10, reference symbol 37 designates rails for guiding the respective arm units 34 and 35. Reference symbol 38 designates guide portions that are formed on the lower surfaces of the respective arm units 34 and 35 so as to engage the arm units 34 and 35 with the rails 37. In FIG. 10, reference symbol 39 designates an opening which is formed at the lower arm unit 35 so as to avoid the movement region of the guide portion 38 of the upper arm unit 34. In FIG. 10, for the sake of a better viewing of the transfer mechanism 31, the respective arm units 34 and 35 are depicted in such a state that they are spaced apart from the transfer base 33.

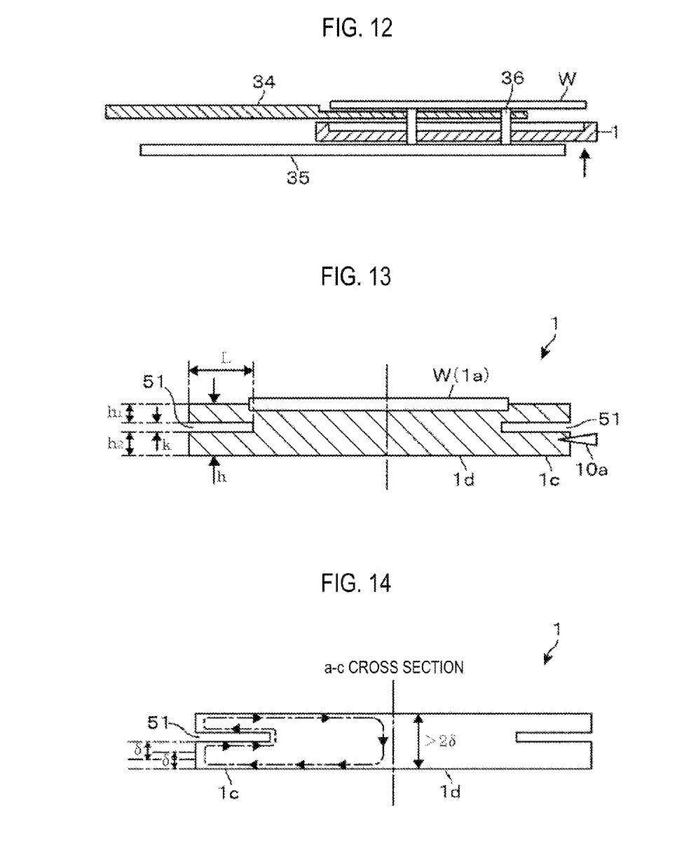

The delivery of the wafer W using the transfer mechanism 31 will be briefly described. First, as shown in FIG. 11, the upper arm unit 34 holding the wafer W and the lower arm unit 35 are brought close to, e.g., the uppermost susceptor 1 of the wafer holder 3 remaining empty (not accommodating the wafer W). Then, the upper arm unit 34 is stopped such that the wafer W is positioned above the susceptor 1. The lower arm unit 35 is also located such that the lifter pins 36 are positioned below the through-holes 1e. Subsequently, as shown in FIG. 12, the lower arm unit 35 is moved upward to allow the lifter pins 36 to receive the wafer W held on the upper arm unit 34. Then, the upper arm unit 34 is moved backward and the lower arm unit 35 is moved downward, thereby mounting the wafer W on the susceptor 1. Similarly, wafers W are loaded onto the remaining susceptors 1. When unloading the wafers W from the wafer holder 3, the respective arm units 34 and 35 are driven in the order opposite to the order of loading the wafers W onto the susceptors 1.

As shown in FIG. 1, a control unit 41 formed of a computer and configured to control the overall operation of the apparatus is installed in the above described film-forming apparatus. A program for executing a below-described film-forming process is stored within a memory of the control unit 41. The program is installed into the control unit 41 from a storage unit 42 as a storage medium such as a hard disk, a compact disk, a magneto-optical disk, a memory card, a flexible disk or the like.

Next, description will be made on the operation of the aforementioned embodiment. First, the gate valve 6 is opened and the wafers W are loaded onto the respective susceptors 1 through the transfer mechanism 31 in the aforementioned manner. Then, the processing vessel 2 is air-tightly closed and the inside of the processing vessel 2 is evacuated. Subsequently, the internal pressure of the processing vessel 2 is set to a processing pressure. While rotating the wafer holder 3 about the vertical axis, electric power is supplied from the high-frequency power supply 27 to the respective coil units 22. The heat generation regulating portion 1c of each of the susceptors 1 is annularly heated by the induced current. The central portion of the susceptor 1 is also heated by the heat transferred from the heat generation regulating portion 1c. Thus, a ridge-shaped temperature distribution is formed at each of the wafers W.

Subsequently, upon supplying a film-forming gas into the processing vessel 2, the film-forming gas flows between one susceptor 1 and another susceptor 1 adjacent to one susceptor 1 at the upper side thereof along the surface of the wafer W mounted on one susceptor 1. Inasmuch as the ridge-shaped temperature distribution in which the temperature becomes higher at the central portion than at the peripheral edge portion is formed at each of the wafers W, the thin film formed on each of the wafers W by the reaction of the film-forming gas has a uniform in-plane thickness.

Now, description will be made on one embodiment of a film-forming gas supply sequence. Specifically, in case of the ALD method described above, a source gas and a reaction gas are alternately supplied into the processing vessel 2. When switching the source gas and the reaction gas, a purge gas such as a nitrogen (N₂) gas or the like is supplied into the processing vessel 2 from a purge gas supply unit not shown, thereby replacing the internal atmosphere of the processing vessel 2. On the other hand, in case of the CVD method, the source gas and the reaction gas are simultaneously supplied into the processing vessel 2. The source gas and the reaction gas react with each other on the surface of the wafer W to form a thin film.

According to the aforementioned embodiment, when a thin film is formed by heating the wafer W on the susceptor 1 through an induction heating of the susceptor 1, the heat generation regulating portion 1c of the susceptor 1 is annularly formed at the outer side of the inner portion 1d so as to include the region that adjoins the outer edge of the wafer W mounted on the inner portion 1d. The thickness dimension H of the heat generation regulating portion 1c is set equal to two times or less of the skin depth δ. For that reason, the heating efficiency of the heat generation regulating portion 1c of the susceptor 1 decreases depending on the thickness dimension H. The amount of the heat transferred to the central portion of the susceptor 1 becomes relatively higher. This makes it possible to heat the inner portion 1d to a temperature higher than the temperature of heat generation regulating portion 1c. Thus, the temperature distribution of the wafer W mounted on the susceptor 1 has a ridge shape. Even if the film-forming gas is supplied to the wafer W at the lateral side thereof, the film-forming gas is difficult to be absorbed at the peripheral edge portion of the wafer W. Consequently, the thickness of the film can be made uniform in the plane of the wafer W.

That is to say, when heating the susceptor 1 by the induction heating, it is typical to design the shape of the susceptor 1 such that larger induced current flows at the susceptor 1. In the present disclosure, the induced current flowing in the heat generation regulating portion 1c is reduced by intentionally adjusting the thickness dimension H of the heat generation regulating portion 1c. For that reason, although the temperature distribution of the wafer W shows a ridge-shaped distribution in the plane of the wafer W, the thickness of the thin film is made uniform. Accordingly, the present application discloses a method which is very effective in performing a film-forming process with respect to a plurality of wafers W stacked like a shelf using a cold wall type induction heating apparatus configured to heat the susceptor 1 by the induction heating and to heat the wafer W through the susceptor 1.

Another embodiment of the susceptor according to the present disclosure will now be described. FIGS. 13 and 14 show an embodiment in which a susceptor 1 is formed into a flat disc shape and in which a groove-shaped notch 51 extending in the horizontal direction is formed on the side circumferential surface of the susceptor 1 along the circumferential direction. That is to say, the susceptor 1 of this embodiment includes an inner portion 1d configured to support an inner region of a wafer and a heat generation regulating portion 1c installed to regulate heat generation at the outer side of the inner portion 1d. The heat generation regulating portion 1c is configured by forming a groove-shaped notch 51 extending in the horizontal direction on the side circumferential surface of the susceptor 1 along the circumferential direction. The temperature of the heat generation regulating portion 1c is made lower than the temperature of the inner portion 1d by adjusting the dimension and number of the notch 51. As described above, when defined based on the diameter dimension (300 mm) of the wafer W, the thickness dimension h of the heat generation regulating portion 1c is 18 mm. The thickness dimensions h1 and h2 of the upper and lower portions existing above and below the notch 51 are 5 mm and 10 mm, respectively. Accordingly, the width dimension k of the notch 51 (the spaced-apart dimension of the upper and lower portions) is, e.g., 3 mm. The depth dimension L spanning from the outer peripheral edge of the susceptor 1 to the inner portion 1d is, e.g., 20 mm. In FIG. 13, a thermocouple 10a is inserted into the side surface of the lower portion.

If the heat generation regulating portion 1c is provided by forming the notch 51 on the side circumferential surface of the susceptor 1 in the above manner, as schematically shown in FIG. 14, an induced current flowing in a loop shape on the vertical cross section of the heat generation regulating portion 1c flows along the notch 51. Since the thickness dimensions h1 and h2 of the upper and lower portions existing above and below the notch 51 are equal to or smaller than 2δ, the currents flowing in the opposite directions through the upper and lower flow paths on the cross sections of the upper and lower portions are cancelled each other. Thus, the induced current is substantially reduced. The thickness of the inner portion 1d of the susceptor 1 is equal to or larger than 2δ. The currents flowing in a loop shape on the cross section of the inner portion 1d do not interfere with each other. Thus, the induced current is not reduced. For that reason, in the heat generation regulating portion 1c, the induced current is reduced depending on the thickness dimension h1 of the upper portion existing above the notch 51 and the thickness dimension h2 of the lower portion existing below the notch 51. As in the aforementioned embodiment, a ridge-shaped temperature distribution can be formed in the wafer W mounted on the susceptor 1. By adjusting the dimensions h, h1 and h2, the temperature gradient from the central portion of the wafer W to the peripheral edge portion of the wafer W can be adjusted in the ridge-shaped temperature distribution.

In the present embodiment, the width dimension k of the notch 51 that constitutes the heat generation regulating portion 1c is set equal to 3 mm. However, as mentioned above, in some embodiments, the width dimension k is set as small as possible such that the heat capacity of the heat generation regulating portion 1c should not be made too small. Since the material of the susceptor 1 is graphite in the present embodiment, the width dimension k of the notch 51 can be reduced to 1 mm in view of the machining accuracy.

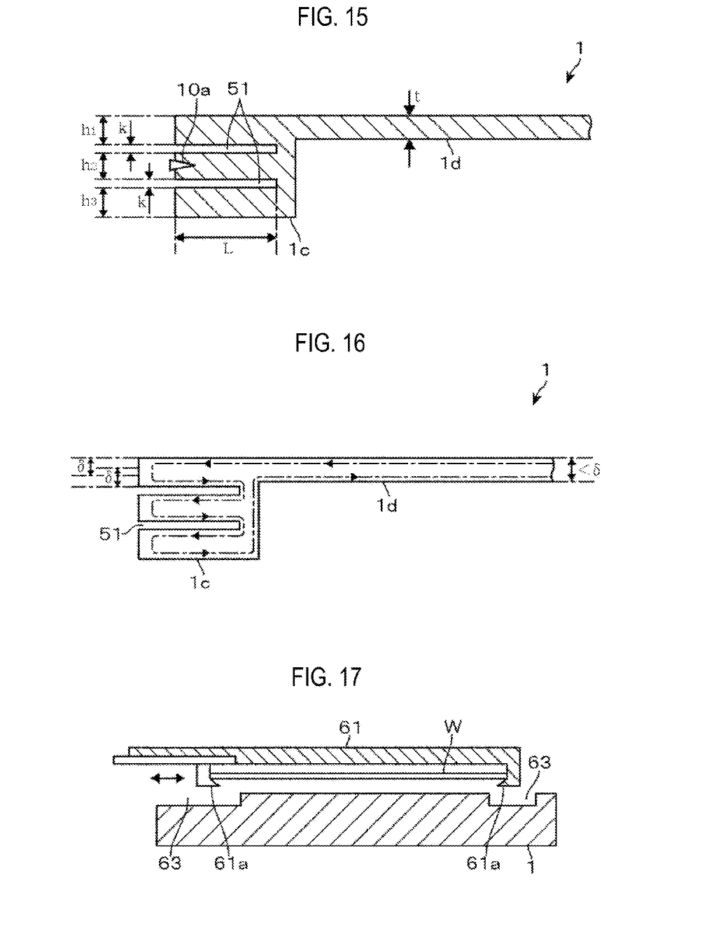

It may be possible to form a plurality of notches 51. FIG. 15 shows a configuration in which, while making the heat capacity of the heat generation regulating portion 1c larger than the heat capacity of the inner portion 1d, the amount of heat generated in the heat generation regulating portion 1c is adjusted by a formation of notches 51 at two upper and lower points. As described above, when defined based on the diameter dimension (300 mm) of the wafer W, the thickness dimension of the heat generation regulating portion 1c is 26 mm. The thickness dimensions h1, h2 and h3 of the upper, middle and lower portions divided by the two notches 51 are 8 mm, respectively. The width dimension k of the notches 51 at two upper and lower points is 1 mm, respectively. The depth dimension L of each of the notches 51 is, e.g., 20 mm. The thermocouple 10a is inserted into the side surface of the middle portion. In contrast, the thickness dimension t of the inner portion 1d of the susceptor 1 is set equal to 5 mm in order to minimize the heat capacity of the inner portion 1d.

If the heat generation regulating portion 1c is provided by forming two notches 51 on the side circumferential surface of the susceptor 1 in the above manner, the induced current flowing on the cross sections of the upper, middle and lower portions can be adjusted by setting the thickness dimensions h1, h2 and h3 of the upper, middle and lower portions to become equal to or smaller than 2δ, as shown in FIG. 16. As described above, the thickness dimension t of the inner portion 1d of the susceptor 1 is smaller than δ. Thus, the induced current does not substantially flow at the inner portion 1d. For that reason, the inner portion 1d of the susceptor 1 is heated by the heat transferred from the heat generation regulating portion 1c toward the center. Consequently, the amount of heat generated in the heat generation regulating portion 1c governs the heating of the susceptor 1.

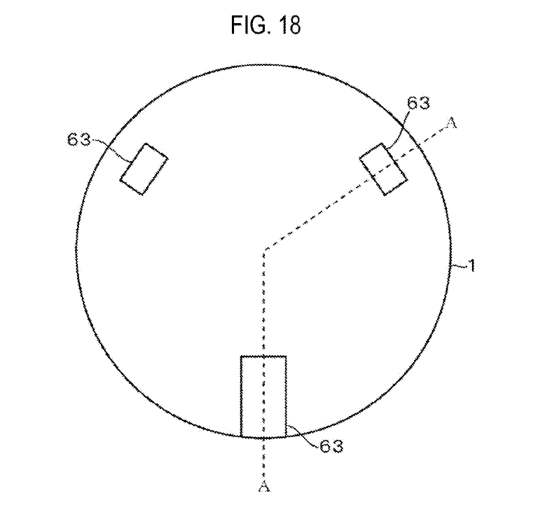

FIG. 17 shows an embodiment in which, when transferring the wafer W to the susceptor 1, the wafer W is gripped at the upper side thereof instead of moving the wafer W up and down by the lifter pins 36 from the lower side of the wafer W. Specifically, on the lower surface of an arm unit 61 for holding the wafer W, claws 61a that wrap around the side circumferential surface of the wafer W to support the lower surface thereof are formed at, e.g., three points, along the circumferential direction. One of the claws 61a (the left claw 61a in FIG. 17) is configured such that it can be horizontally moved forward and backward along the radial direction of the wafer W by a drive unit not shown. When holding the wafer W, the left claw 61a moves forward toward the center of the wafer W. When delivering the wafer W to the susceptor 1, the left claw 61a moves backward toward the outer edge of the wafer W. As shown in FIG. 18, depressions 63 are formed on the surface of the susceptor 1 so as to avoid the formation regions of the respective claws 61a and the movement region of the claw 61a capable of moving forward and backward.

Use of this wafer holding mechanism eliminates the need to perform a complex machining work with respect to the susceptor 1. Moreover, it is only necessary to use a single arm unit 61 for holding the wafer W. This makes it possible to simplify the apparatus.

The heat generation regulating portion 1c is formed in an annular shape along the outer peripheral edge of the susceptor 1 when seen in a plan view. In this case, the heat generation regulating portion 1c may be formed at a position shifted from the outer periphery portion of the susceptor 1 toward the central portion of the wafer W or may be formed at a location shifted outward from the outer periphery portion of the susceptor 1. In other words, the heat generation regulating portion 1c may be arranged so as to heat the outer peripheral edge of the wafer W mounted on the susceptor 1 and such that the inner portion of the wafer W is heated by the heat transferred from the outer peripheral edge of the wafer W. When delivering the wafer W to the susceptor 1, the transfer mechanism 31 is moved forward and backward while keeping the wafer holder 3 accommodated within the processing vessel 2. Alternatively, the wafer holder 3 may be taken out from the processing vessel 2 into a laterally shifted region by a transfer device not shown. The wafer W may be delivered to the susceptor 1 at the laterally shifted region.

The wafer holder 3 is configured such that it can be rotated about the vertical axis. Alternatively, the coil units 22 may be disposed at a plurality of points at a regular interval at the outer side of the processing vessel 2 when seen in a plan view such that, even if the wafer holder 3 is not rotated, magnetic lines are formed along the circumferential direction of the susceptor 1. Accordingly, the susceptor 1 of the present disclosure may be formed into, e.g., a rectangular shape rather than a circular shape when seen in a plan view and may be applied to an embodiment where a thin film is formed on a glass substrate for an LCD (Liquid Crystal Display).

In the foregoing embodiment, description has been made on the embodiment in which the thin film is formed on the surface of the wafer W. However, instead of the formation of the thin film, an oxidizing treatment or a modifying treatment may be performed as the heat treatment for the wafer W. Specifically, in case of performing the oxidizing treatment, an oxidizing gas (an oxygen (O₂) gas or an ozone (O₃) gas) is used as a treatment gas. In case of performing the modifying treatment, water (H₂O) vapor is used as a treatment gas. Even when performing the oxidizing treatment or the modifying treatment, a ridge-shaped temperature distribution is formed at the respective wafer W. Thus, this treatment through the use of the treatment gas is uniformly performed at the plane of the wafer W, and accordingly it becomes possible to perform a uniform heat treatment.

### Example

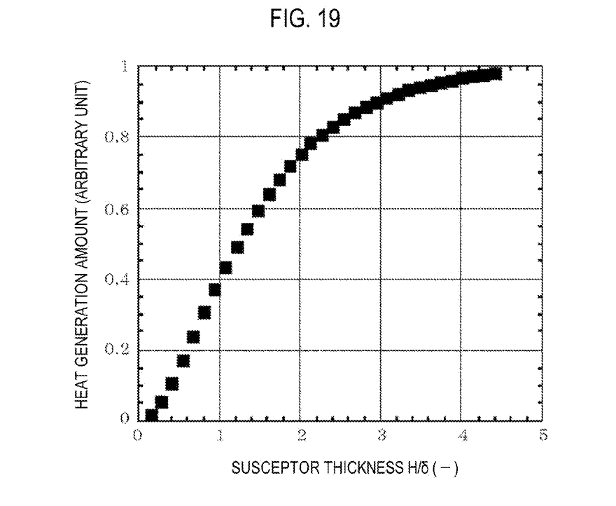

Next, description will be made on an example implemented with respect to the present disclosure. FIG. 19 is a graph that explains why the thickness dimension H of the heat generation regulating portion 1c of the susceptor 1 is set equal to or smaller than two times of the skin depth δ as mentioned above. In the graph shown in FIG. 19, the horizontal axis indicates H/δ which is obtained by dividing the thickness dimension H by the skin depth δ. The vertical axis indicates a relative amount of heat generation which becomes equal to 1 when the thickness dimension H is infinite. The amount of heat generation sharply increases as the thickness dimension H of the heat generation regulating portion 1c grows larger. If the thickness dimension H of the heat generation regulating portion 1c exceeds two times of the skin depth δ, the increment is gentle and the amount of heat generation becomes gradually saturated.

If the thickness dimension H of the heat generation regulating portion 1c is set equal to or smaller than two times of the skin depth δ, as compared to a case where the thickness dimension H is set greater than two times of the skin depth δ, it is possible to reduce the heat generation efficiency of the induced current at the heat generation regulating portion 1c. For that reason, as described above, the temperature distribution of the wafer W mounted on the susceptor 1 can be set in a ridge shape.

Even when the heat generation regulating portion 1c is provided by forming the notch 51 on the side circumferential surface of the susceptor 1 as described above, if the thickness dimension of the respective portions divided by the notch 51 is set equal to or smaller than two times of the skin depth δ, the heat generation efficiency of the heat generation regulating portion 1c can be reduced and the temperature distribution of the wafer W mounted on the susceptor 1 can be adjusted into a ridge shape.

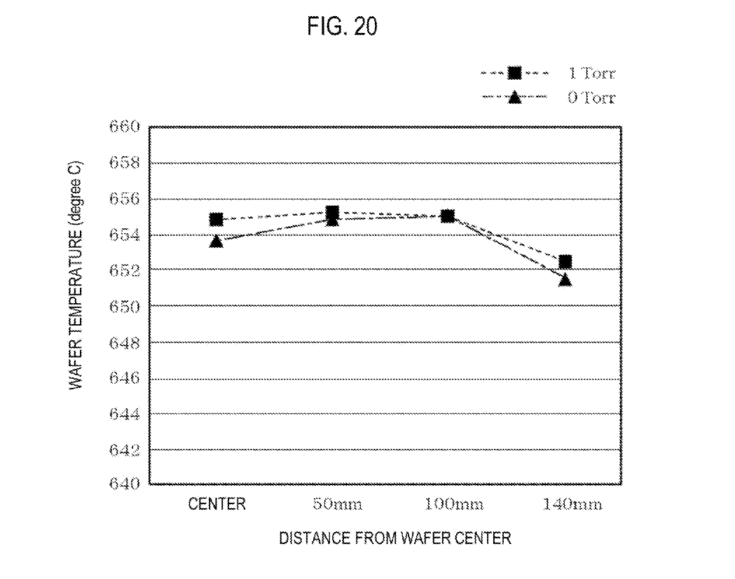

FIG. 20 shows the results of the measurement of the temperature distribution at the wafer W mounted on the susceptor 1 when the susceptor 1 (having a thickness dimension H of 15 mm) shown in FIG. 3 is accommodated within the processing vessel 2 and heated by the induced current. The measurement was conducted for a case where the internal pressure of the processing vessel 2 is set at 0 Pa (0 Torr) and at 133 Pa (1 Torr). In FIG. 20, the temperature distribution at the wafer W is indicated along the radius of the wafer W extending from the central portion of the wafer W to the outer edge portion thereof.

As a result, the temperature distribution at the wafer W was set in a ridge shape regardless of the internal pressure of the processing vessel 2.

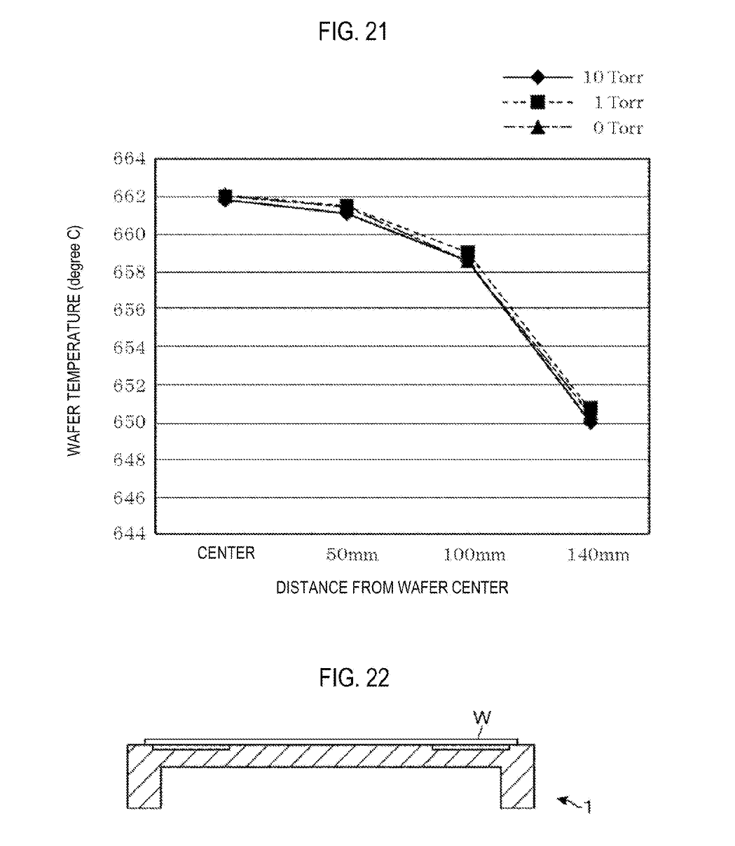

FIG. 21 shows the results of the measurement of the temperature distribution at the wafer W mounted on the susceptor 1 shown in FIGS. 13 and 14. In this case, the degree of the ridge-shaped temperature distribution at the wafer W is higher. In FIG. 21, the heating temperature of the susceptor 1 is set at 650 degrees C.

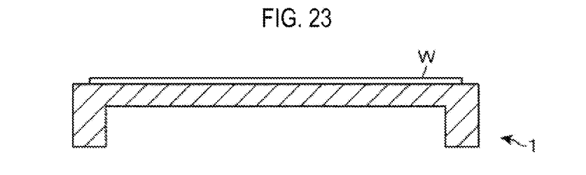

The results of the measurement of the temperature distribution at the wafer W mounted on the susceptor 1 when the thickness dimension H of the heat generation regulating portion 1c is set equal to 18 mm (equal to or greater than two times of the skin depth δ) will now be described. The measurement was conducted with respect to two kinds of the shape of the susceptor 1 shown in FIGS. 22 and 23.

In FIG. 22, the thickness dimension H of the heat generation regulating portion 1c is set equal to 18 mm. The mounting region 1a is not formed at the susceptor 1. A depression having a depth dimension of 1 mm is formed at a more inward position than the outer peripheral edge of the wafer W along the outer peripheral edge so as to extend in the circumferential direction. Thus, the wafer W is supported by the susceptor 1 at the position near the central portion and at the outer peripheral edge of the wafer W. FIG. 23 shows an embodiment in which the thickness dimension H of the susceptor 1 having the same configuration as the susceptor 1 shown in FIG. 3 is set equal to 18 mm.

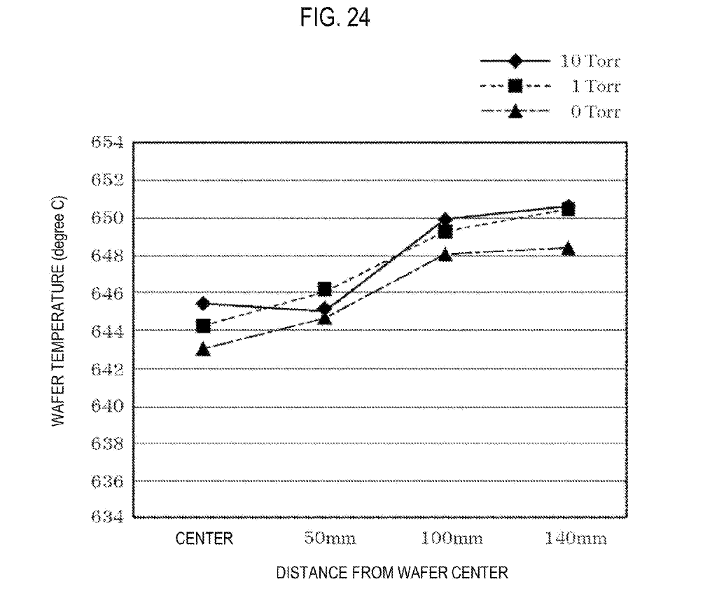

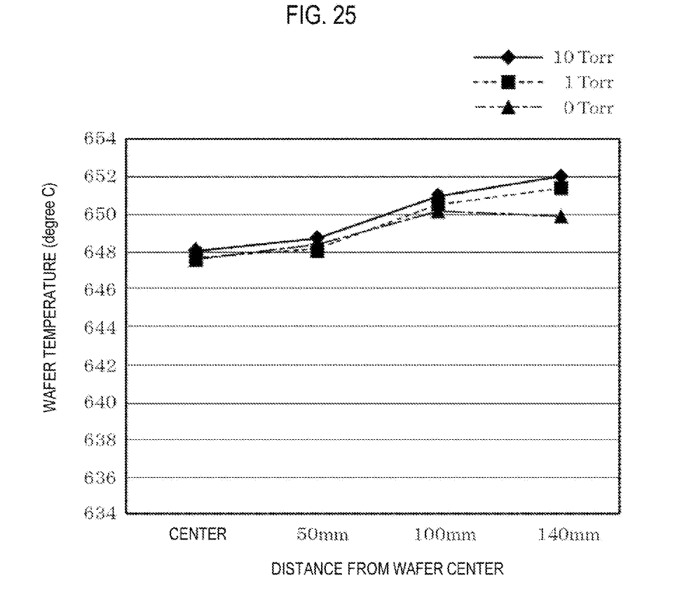

FIGS. 24 and 25 show the results of the measurement of the temperature distribution with respect to the susceptors 1 shown in FIGS. 22 and 23. In any of the embodiments, regardless of the pressure, the temperature at the outer periphery portion of the wafer W is higher than the temperature at the central portion. Thus, the temperature distribution has a so-called valley shape. Accordingly, the method of the present disclosure is very effective in adjusting the temperature distribution of the wafer W into a ridge shape.

According to the present disclosure, when a heat treatment is performed by heating the substrate on the mounting stand through an induction heating of the mounting stand, the mounting stand is configured by the inner portion that supports the inner region of the substrate and the heat generation regulating portion that regulates the amount of heat generation at the outer periphery side of the inner portion. The thickness dimension of the heat generation regulating portion is set or the groove-shaped notch is formed at the heat generation regulating portion such that the temperature of the heat generation regulating portion becomes lower than the temperature of the inner portion. For that reason, the mounting stand is heated while maintaining a balance between the amount of heat generation at the heat generation regulating portion and the amount of the heat transferred from the heat generation regulating portion to the inner portion. Thus, the temperature distribution at the substrate mounted on the mounting stand can be adjusted into a ridge shape (a state in which the temperature of the central portion becomes higher than the temperature of the peripheral edge portion). Accordingly, even if a treatment gas is supplied to the substrate at the lateral side thereof, the treatment gas is difficult to be absorbed at the peripheral edge portion of the substrate. As a result, the concentration of the treatment gas can be made uniform at the plane of the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An apparatus of performing a heat treatment with respect to a substrate mounted within a processing vessel, comprising:
a mounting stand on which the substrate is mounted, the mounting stand including an inner portion configured to transfer heat from an outer periphery portion of the substrate to a central portion of the substrate, and a heat generation regulating portion annularly installed at the outer periphery portion of the inner portion so as to extend along a circumferential direction and configured to generate heat through an induction heating;
a magnetic field forming mechanism designed to form magnetic fields by alternating current power supplied to the magnetic field forming mechanism, and configured to inductively heat the heat generation regulating portion by allowing magnetic fluxes parallel to a mounting surface of the inner portion to pass through the heat generation regulating portion;
a power supply unit configured to supply the alternating current power to the magnetic field forming mechanism;
a temperature measuring unit configured to measure a temperature of the heat generation regulating portion;
a control unit configured to control the alternating current power supplied to the magnetic field forming mechanism, based on a temperature value measured by the temperature measuring unit and a target temperature; and
a gas supply unit configured to supply a treatment gas to the substrate mounted on the mounting stand from a peripheral edge of the mounting stand,
the heat generation regulating portion having a thickness dimension set equal to or smaller than two times of a skin depth which is decided based on a magnetic permeability and resistivity of the heat generation regulating portion and a frequency of the alternating current power.

2. An apparatus of performing a heat treatment with respect to a substrate mounted within a processing vessel, comprising:
a mounting stand including an inner portion on which the substrate is mounted and a heat generation regulating portion installed at a peripheral edge portion of the inner portion and configured to generate heat through an induction heating, the heat generation regulating portion including an outer end surface and a notch cut on the outer end surface to annularly extend along a circumferential direction such that a temperature of a central portion of the inner portion becomes higher than a temperature of the heat generation regulating portion;
a magnetic field forming mechanism designed to form magnetic fields by alternating current power supplied to the magnetic field forming mechanism and configured to inductively heat the heat generation regulating portion by allowing magnetic fluxes parallel to a mounting surface of the inner portion to pass through the heat generation regulating portion;
a power supply unit configured to supply the alternating current power to the magnetic field forming mechanism;
a temperature measuring unit configured to measure the temperature of the heat generation regulating portion;
a control unit configured to control the alternating current power supplied to the magnetic field forming mechanism, based on a temperature value measured by the temperature measuring unit and a target temperature; and
a gas supply unit configured to supply a treatment gas to the substrate mounted on the mounting stand from a peripheral edge of the mounting stand.

3. The apparatus of claim 1, further comprising:
a rotating mechanism configured to rotate the mounting stand about an axis extending from a central portion of the mounting stand perpendicularly to the mounting surface of the mounting stand when seen in a plan view.

4. The apparatus of claim 1, wherein the mounting stand includes a plurality of mounting stands stacked one above another, the gas supply unit installed between an inner wall of the processing vessel and a side surface of the mounting stand.

5. A method of performing a heat treatment with respect to a substrate mounted within a processing vessel, comprising:
mounting the substrate on an inner portion;
inductively heating a heat generation regulating portion annularly installed in an outer periphery portion of the inner portion to extend along a circumferential direction, by supplying alternating current power to a magnetic field forming mechanism and by allowing magnetic fluxes parallel to a mounting surface of the inner portion to pass through the heat generation regulating portion, and transferring heat from the heat generation regulating portion to a central portion of the inner portion through the inner portion;
measuring a temperature of the heat generation regulating portion;
controlling the alternating current power supplied to the magnetic field forming mechanism, based on a measured temperature value of the heat generation regulating portion and a target temperature; and
supplying a treatment gas to the substrate mounted on the inner portion from a peripheral edge of the inner portion,
the heat generation regulating portion having a thickness dimension set equal to or smaller than two times of a skin depth which is decided based on a magnetic permeability and resistivity of the heat generation regulating portion and a frequency of the alternating current power, whereby the heat treatment is performed in such a state that a temperature of a central portion of the substrate is higher than a temperature of a peripheral edge portion of the substrate.

6. A method of performing a heat treatment with respect to a substrate mounted within a processing vessel, comprising:
mounting the substrate on an inner portion;
inductively heating a heat generation regulating portion annularly installed in an outer periphery portion of the inner portion and provided with an outer end surface and a notch cut on the outer end surface to annularly extend along a circumferential direction, by supplying alternating current power to a magnetic field forming mechanism and by allowing magnetic fluxes parallel to a mounting surface of the inner portion to pass through the heat generation regulating portion, and transferring heat from the heat generation regulating portion to a central portion of the inner portion through the inner portion such that a temperature of a central portion of the substrate becomes higher than a temperature of a peripheral edge portion of the substrate;
measuring a temperature of the heat generation regulating portion;
controlling the alternating current power supplied to the magnetic field forming mechanism, based on a measured temperature value of the heat generation regulating portion and a target temperature; and
supplying a treatment gas to the substrate mounted on the inner portion from a peripheral edge of the inner portion.

7. The method of claim 5, wherein the heat treatment of the substrate is performed by rotating the inner portion about an axis extending from a central portion of the inner portion perpendicularly to the mounting surface of the inner portion when seen in a plan view.
